(19) United States
(12) Patent Application Publication
(10) Pub. No.: US 2008/0122105 A1
(43) Pub. Date: May 29, 2008

(54) STRUCTURE FOR PREVENTING PAD PEELING AND METHOD OF FABRICATING THE SAME

(76) Inventor: Ping-Chang Wu, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,203

(22) Filed: Jul. 13, 2006

(51) Int. Cl. H01L 23/488; H01L 21/44

(52) U.S. Cl. 257/773; 438/612; 257/E21.476; 257/E23.023

(57) ABSTRACT

A method of fabricating the structure for preventing the pad peeling is provided. A semiconductor substrate in which an active circuit structure has been formed is provided. Then, a dielectric layer with an opening is formed on the semiconductor substrate. The opening is formed in the dielectric layer above the edge position of the corresponding active circuit structure, and exposes a part of the surface of the active circuit structure. Then, a pad is formed above the semiconductor substrate to electrically connect the active circuit structure. The pad covers the dielectric layer above the position of the corresponding active circuit structure and fills up the opening. Then, a protective layer is formed to cover the surface of the dielectric layer and the edge of the pad.

### BACKGROUND OF THE INVENTION

1. Field of Invention

The present invention generally relates to a technology of a pad of an integrated circuit. More particularly, the present invention relates to a structure for preventing pad peeling and a method of fabricating the same.

2. Description of Related Art

Generally speaking, for semiconductor devices, pad metal layers formed on the surface act as the connection interface between the internal circuit and the external signal, and are electrically connected to the internal circuit. In the semiconductor device packaging technique, after the integrated circuit device is finished, a step of cutting a wafer into dies must be further included. Subsequently, a die bonding step is carried out. Then, wire bonding is performed to electrically connect the external circuit and the pad metal layer with Au metal wire. And then a molding step is carried out, and thus the whole semiconductor device packaging process is completed.

Typical pad metal layers are usually rectangular or square, so relatively high levels of stress may occur at the corner of the pad metal layer. Therefore, when the wire bonding process (or welding process) is performed on the pad, due to the improper parameter control, the pad metal layer is likely to bear extremely high levels of stress, thus causing the pad metal layer to peel and further damaging the device under the pad metal layer.

Particularly, with the continuous development of the process, the use of a pad metal layer formed by a manner of fine pitch wire bonding may aggravate the peeling of the pad metal layer. Therefore, those skilled in the art have devoted themselves to solving the problem of the pad metal layer peeling off during the semiconductor device packaging process due to the extremely high stress which negatively affects the process yield.

Moreover, techniques related to the above are disclosed in some US patents, for example, U.S. Pat. No. 6,590,296, U.S. Pat. No. 5,300,815, U.S. Pat. No. 5,925,935, and U.S. Pat. No. 6,858,944 etc., the entire content of which are incorporated herein by reference.

### SUMMARY OF THE INVENTION

Accordingly, the objective of the present invention is to provide a method of fabricating a structure for preventing the pad peeling, thus preventing various problems that may incur because of the peeling of the pad that easily occurs during the process of wire bonding.

Another objective of the present invention is to provide a structure for preventing the pad peeling, thus avoiding the peeling of the pad which damages the device under the pad.

Still another objective of the present invention is to provide a method of fabricating the structure for preventing the pad peeling, thus overcoming various problems that may incur due to the peeling of the pad that easily occurs during the process of wire bonding.

Yet another objective of the present invention is to provide a structure for preventing the pad peeling, thus avoiding the peeling of the pad which damages the device under the pad.

The present invention provides a method of fabricating a structure for preventing the pad peeling. A semiconductor substrate is provided, in which an active circuit structure has been formed. Next, a dielectric layer with an opening is formed on the semiconductor substrate, in which the opening is formed in the dielectric layer above the edge position of the corresponding active circuit structure, and exposes a part of the surface of the active circuit structure. Then, a pad is formed above the semiconductor substrate to electrically connect the active circuit structure, in which the pad covers the dielectric layer above the position of the corresponding active circuit structure and fills up the opening. After that, a protective layer is formed to cover the surface of the dielectric layer and the edge of the pad.

According to the method of fabricating the structure for preventing the pad peeling of the embodiment of the present invention, the pad is, for example, a metal layer made of, for example, aluminum.

According to the method of fabricating the structure for preventing the pad peeling of the embodiment of the present invention, the opening is, for example, a trench or a hole.

According to the method of fabricating the structure for preventing the pad peeling of the embodiment of the present invention, the material of the protective layer is, for example, an insulating material.

The present invention further provides a structure for preventing the pad peeling, which comprises a semiconductor substrate, a dielectric layer, a pad, and a protective layer. The semiconductor substrate has an active circuit structure. The dielectric layer is disposed on the semiconductor substrate and has an opening. The opening is disposed in the dielectric layer above the edge position of the corresponding active circuit structure, and exposes a part of the surface of the active circuit structure. The pad is disposed above the semiconductor substrate and covers the dielectric layer above the position of the corresponding active circuit structure and fills up the opening. The protective layer is disposed on the dielectric layer and covers the edge of the pad.

According to the structure for preventing the pad peeling of the embodiment of the present invention, the pad is for example a metal layer, and the material of the metal layer is for example aluminum.

According to the structure for preventing the pad peeling of the embodiment of the present invention, the opening is, for example, a trench or a hole.

According to the structure for preventing the pad peeling of the embodiment of the present invention, the material of the protective layer is, for example, an insulating material.

The present invention further provides a method of fabricating a structure for preventing the pad peeling. A semiconductor substrate is provided, in which an active circuit structure has been formed. Next, a dielectric layer and a patterned photoresist layer are sequentially formed on the semiconductor substrate, wherein the patterned photoresist layer exposes the dielectric layer surface above a part of the semiconductor substrate of the corresponding active circuit structure and the side edge thereof. Then, an etching process is performed to remove the exposed dielectric layer and a part of the semiconductor substrate under the dielectric layer with the patterned photoresist layer as a mask, so as to form an opening in the semiconductor substrate. Then, the patterned photoresist layer is removed. After that, a pad is formed to electrically connect the active circuit structure, in which the pad covers the surface of the active circuit structure and a part of the dielectric layer and fills up the opening. And then, a protective layer is formed to cover the surface of the dielectric layer and the edge of the pad.

According to the method of fabricating the structure for preventing the pad peeling of the embodiment of the present invention, the patterned photoresist layer further includes, for example, the surface covering a part of the edge and/or corner of the active circuit structure.

According to the method of fabricating the structure for preventing the pad peeling of the embodiment of the present invention, the pad is, for example, a metal layer made of, for example, aluminum.

According to the method of fabricating the structure for preventing the pad peeling in the embodiment of the present invention, the material of the protective layer is, for example, an insulating material.

The present invention further provides a structure for preventing the pad peeling, which comprises a semiconductor substrate, a dielectric layer, a pad, and a protective layer. The semiconductor substrate has an active circuit structure therein, and the semiconductor substrate of the side edge of the active circuit structure has an opening therein. The dielectric layer is disposed on the semiconductor substrate and exposes the surface of the active circuit structure and a part of the surface of the semiconductor substrate of the side edge of the active circuit structure. The pad is disposed above the semiconductor substrate and covers the active circuit structure and a part of the dielectric layer, and fills up the opening. The protective layer is disposed on the dielectric layer and covers the edge of the pad.

According to the structure for preventing the pad peeling of the embodiment of the present invention, the dielectric layer further includes, for example, the surface disposed on a part of the edge and/or corner of the active circuit structure.

According to the structure for preventing the pad peeling of the embodiment of the present invention, the pad is, for example, a metal layer made of, for example, aluminum.

According to the structure for preventing the pad peeling of the embodiment of the present invention, the material of the protective layer is, for example, an insulating material.

According to the method of the present invention, a part of the pad formed in the opening and serving as a via is used to electrically connect the whole pad to the internal circuit. The protective layer formed later covers the edge of the pad, thus enhancing the bonding level of the edge of the pad and particularly enhancing the bonding level of the corner of the pad. Therefore, during the subsequent wire bonding process, the peeling of the pad can be avoided, which is caused by the pad, especially the corner of the pad, bearing an extremely high stress due to the upward tension after wiring, and further damages the active circuit structure under the pad. Moreover, according to another method of the present invention, the contact area of the pad and the conductive layer under the pad is increased, and the clamping force of the pad is used to resist the upward tension in the wire bonding process, thus preventing the pad, especially the corner of the pad, from bearing the extremely high stress. The extremely high stress causes the peeling of the pad, and further damages the active circuit structure under the pad. In another aspect, compared with the method of the convention art, the process of the present invention is not complicated, and an additional mask is not required to achieve the objective of preventing the pad from peeling, thus saving the cost of the additional mask.

In order to make the aforementioned and other objectives, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are schematic cross-sectional views of the flow of the method of fabricating the structure for preventing the pad peeling according to an embodiment of the present invention.

FIG. 2 is a schematic top view of FIG. 1B, and FIG. 1B is a schematic cross-sectional view along section line I-I′ of FIG. 2.

FIG. 3 is another schematic top view of FIG. 1B, and FIG. 1B is a schematic cross-sectional view along section line II-II′ of FIG. 3.

FIG. 4A to FIG. 4E are schematic cross-sectional views of the flow of the method of fabricating the structure for preventing the pad peeling according to another embodiment of the present invention.

FIG. 5 is a schematic top view of FIG. 4B, and FIG. 4B is a schematic cross-sectional view along section line III-III′ of FIG. 5.

FIG. 6 to FIG. 9 are the other schematic top views of FIG. 4B.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

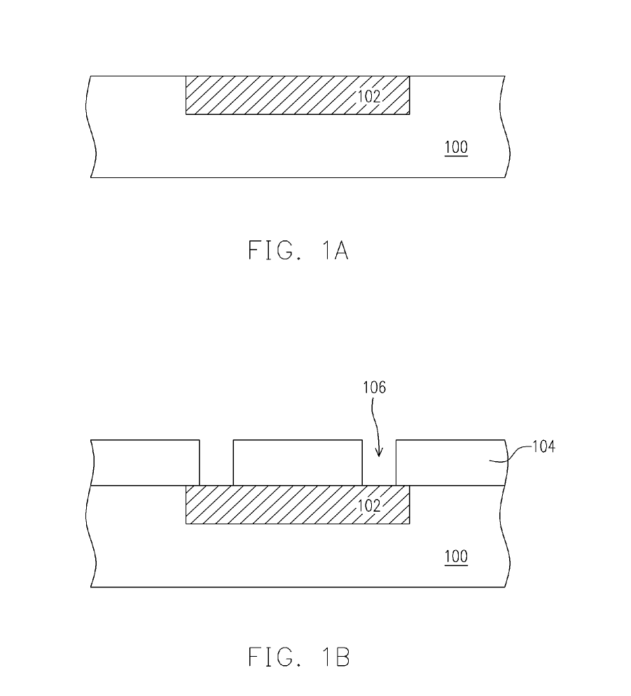

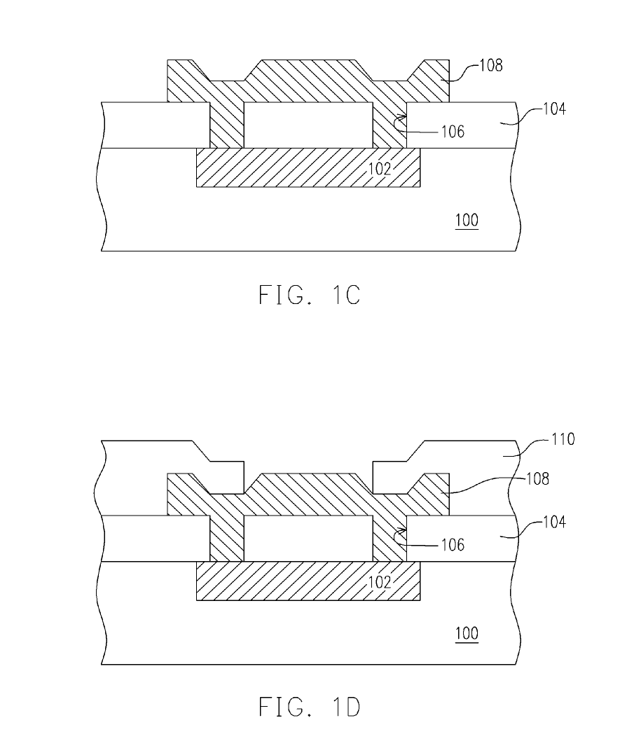

FIG. 1A to FIG. 1D are schematic cross-sectional views of the flow of the method of fabricating the structure for preventing the pad peeling according to an embodiment of the present invention.

First, referring to FIG. 1A, a semiconductor substrate 100 is provided, in which an active circuit structure (not shown) has been formed. In order to simplify the drawing, only the topmost conductive layer 102 of the active circuit structure is shown in FIG. 1A, and not all of the devices in the active circuit structure are shown. It should be apparent to those skilled in the art that the active circuit structure includes, for example, a plurality of circuit devices and a plurality of metal interconnects. In the present embodiment, the conductive layer 102 represents the active circuit structure in the semiconductor substrate 100.

Then, referring to 1B, a dielectric layer 104 is formed on the semiconductor substrate 100. The material of the dielectric layer 104 is, for example, silicon dioxide, silicon nitride, or any appropriate dielectric materials. The method of forming the dielectric layer 104 is, for example, chemical vapor deposition.

Then, referring to FIG. 1B, an opening 106 is formed in the dielectric layer 104. The opening 106 is formed in the dielectric layer 104 above the edge position of the corresponding conductive layer 102, and the bottom of the opening 106 exposes a part of the surface of the conductive layer 104.

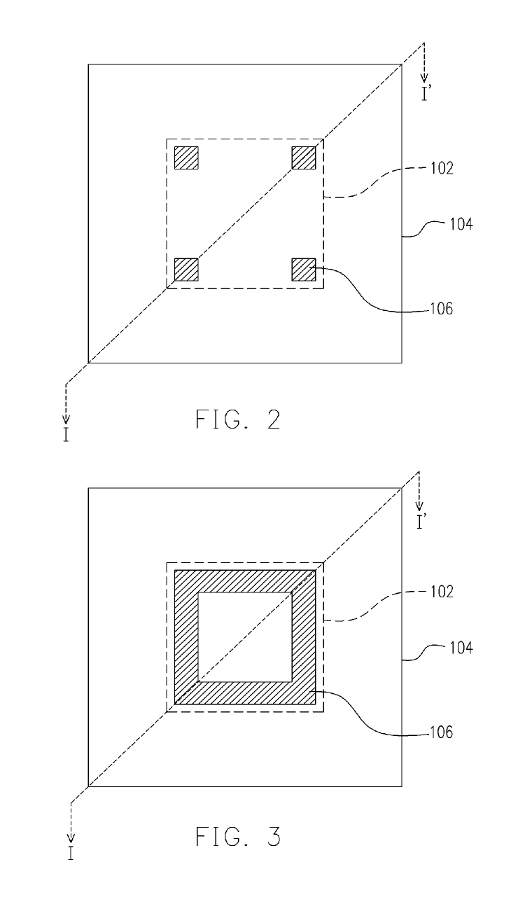

In the embodiment, the opening 106 is, for example, a hole. As shown in FIG. 2, the opening 106 is four holes. FIG. 1B is a schematic cross-sectional view along section line I-I′ of FIG. 2. The method of forming the opening 106 is, for example, forming a patterned photoresist layer (not shown) on the dielectric layer 104. The pattern of the patterned photoresist layer is four holes exposing a part of the surface of the dielectric layer 104, and the pattern of the patterned photoresist layer is formed in the dielectric layer 104 above the edge position of the corresponding conductive layer 102. Then, the patterned photoresist layer is used as a mask to etch the exposed dielectric layer 104, thus completing the formation.

In another embodiment, the opening 106 is, for example, a trench. As shown in FIG. 3, the opening 106 is a ring trench. FIG. 1B is a schematic cross-sectional view along section line II-II′ of FIG. 3.

Definitely, the opening 106 is not limited to the hole or trench as shown in the above embodiments, and the shape and the quantity of the opening 106 are not limited in the present invention.

After that, referring to FIG. 1C, a pad 108 is formed above the semiconductor substrate 100 to electrically connect the conductive layer 102. The pad 108 covers the dielectric layer 104 above the position of the corresponding conductive layer 102 and fills up the opening 106. The pad 108 is, for example, a metal layer made of, for example, aluminum metal. The method of forming the pad 108 is, for example, forming an aluminum metal layer (not shown) above the semiconductor substrate 100, so as to cover the whole dielectric layer 104 and fill up the opening 106. Then, a patterned photoresist layer (not shown) is formed on the aluminum metal layer, so as to expose the aluminum metal layer above the position of the corresponding conductive layer 102. After that, the patterned photoresist layer is used as a mask to etch the exposed aluminum metal layer, thus completing the formation.

The part of the pad 108 formed in the opening 106 has the function of via, such that the pad 108 can be electrically connected to the conductive layer 102.

Then, referring to FIG. 1D, a protective layer 110 is formed to cover the surface of the dielectric layer 104 and the edge of the pad 108. The material of the protective layer 110 is, for example, an insulating material, and the forming method thereof is, for example, chemical vapor deposition.

Then, the wire bonding process can be carried out subsequently, so as to electrically connect the external circuit and the pad 108 by forming the welding wire (not shown). Then, the molding step is carried out, and thus the semiconductor device packaging process is completed. The subsequent wire bonding and molding steps are known to the technicians in the art, and the details will not be described herein again.

It should be noted that different from the conventional art in which the whole pad contacts and is electrically connected to the internal circuit, in the method of the present invention, a part of the pad formed in the opening serves as the via to electrically connect the whole pad to the internal circuit. The protective layer formed later covers the edge of the pad, thus enhancing the bonding level of the edge of the pad, and especially enhancing the bonding level of the corner of the pad. Therefore, during the subsequent wire bonding process, the peeling of the pad can be avoided, which is caused by the pad, especially the corner of the pad, bearing an extremely high stress due to the upward tension after wiring, and further damages the active circuit structure under the pad.

Moreover, compared with the method of the conventional art, the process of the present invention is not complicated, and an additional mask is not required to achieve the objective of preventing the pad from peeling, thus saving the cost of the additional mask.

The structure for preventing the pad peeling of an embodiment of the present invention is illustrated as follows.

Referring to FIG. 1D, the structure for preventing the pad peeling of the present embodiment comprises a semiconductor substrate 100, a dielectric layer 104, a pad 108, and a protective layer 110. The semiconductor substrate 100 has an active circuit structure (not shown). In the present embodiment, only the conductive layer 102 as shown in the figure represents the active circuit structure of the semiconductor substrate 100. The dielectric layer 104 is disposed above the semiconductor substrate 100, and the dielectric layer 104 has an opening 106. The opening 106 is, for example, a hole or a trench. Especially, the opening 106 is disposed in the dielectric layer 104 above the edge position of the corresponding conductive layer 102, and the bottom of the opening 106 exposes a part of the surface of the conductive layer 102. Moreover, the pad 108 is disposed above the semiconductor substrate 100 and covers the dielectric layer 104 above the position of the corresponding conductive layer 102, and fills up the opening 106. The pad 108 is, for example, a metal layer made of, for example, aluminum metal. The protective layer 110 is disposed on the dielectric layer 104 and covers the edge of the pad 108. The material of the protective layer 110 is, for example, an insulating material.

The structure of the present invention can enhance the bonding level of the edge of the pad, and especially enhance the bonding level of the corner of the pad. Therefore, in the subsequent wire bonding process, the peeling of pad which further damages the active circuit structure under the pad can be prevented.

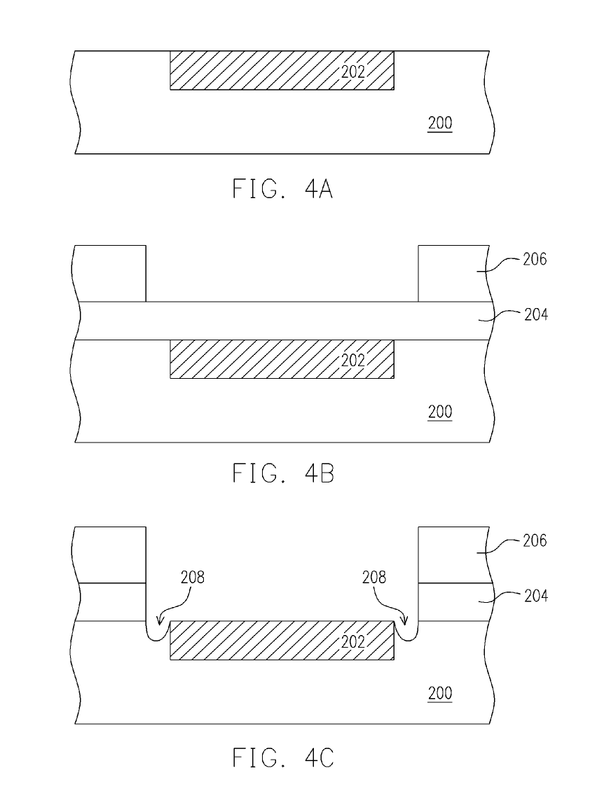

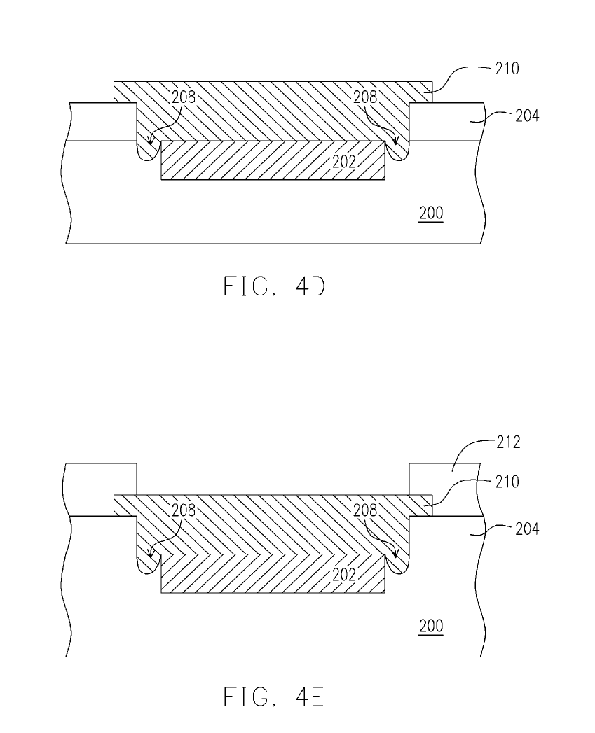

FIG. 4A to FIG. 4E are schematic cross-sectional views of the flow of the method of fabricating the structure for preventing the pad peeling according to another embodiment of the present invention.

First, referring to FIG. 4A, a semiconductor substrate 200 is provided, in which an active circuit structure (not shown) has been formed. In order to simplify the drawing, only the topmost conductive layer 202 of the active circuit structure is shown in FIG. 4A, and not all of the devices in the active circuit structure are shown. However, it is known to those skilled in the art that the active circuit structure includes, for example, a plurality of circuit devices and a plurality of metal interconnects. In the present embodiment, the conductive layer 202 represents the active circuit structure of the semiconductor substrate 200.

Then, referring to 4B, a dielectric layer 204 and a patterned photoresist layer 206 are sequentially formed on the semiconductor substrate 200. The patterned photoresist layer 206 exposes the surface of the dielectric layer 204 above the position of the corresponding conductive layer 202, and exposes the surface of the dielectric layer 204 above a part of the semiconductor substrate 100 of the side edge of the conductive layer 202.

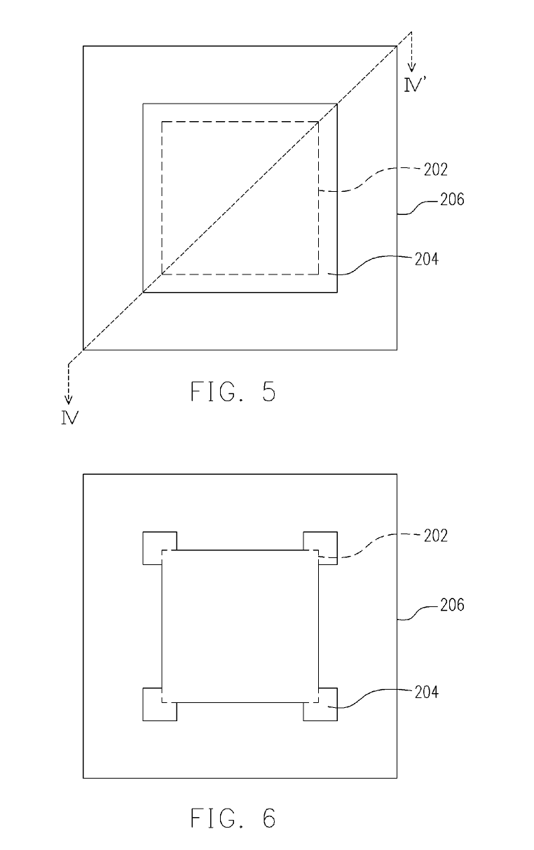

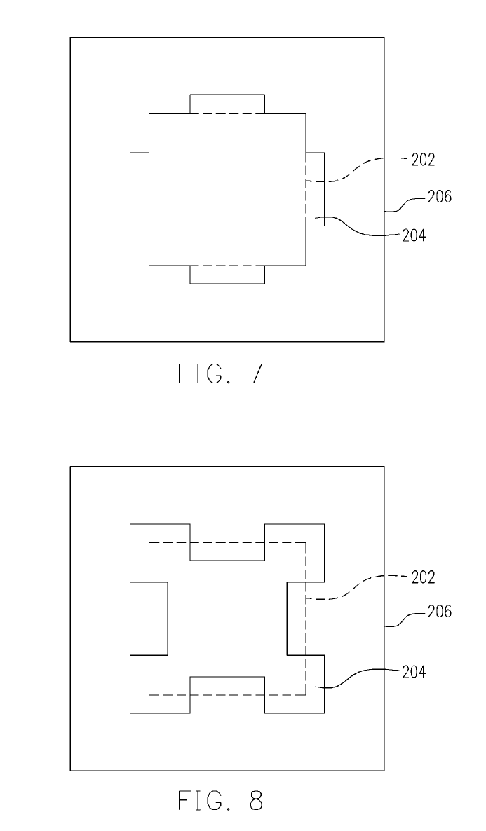

In the present embodiment, the patterned photoresist layer 206 is of, for example, the pattern as shown in FIG. 5. FIG. 4B is a schematic cross-sectional view along section line III-III′ of FIG. 5. In an embodiment, the patterned photoresist layer 206 is of, for example, the pattern as shown in FIG. 6 and FIG. 7.

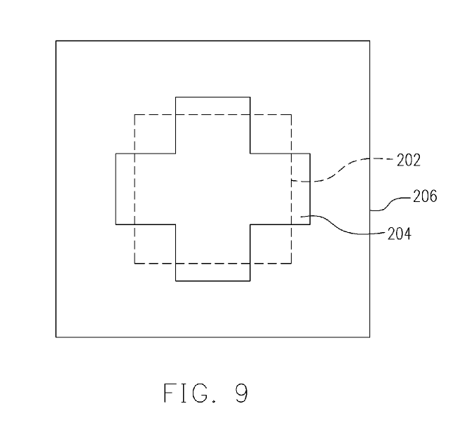

Further, the patterned photoresist layer 206 can further comprise the surface covering a part of the edge and/or corner of the conductive layer 202. In an embodiment, the patterned photoresist layer 206 is of, for example, the pattern as shown in FIG. 8 and FIG. 9.

Definitely, the pattern of the patterned photoresist layer 206 in the above embodiment is illustrated as an example. The shape of the pattern of the patterned photoresist layer 206 is not limited in the present invention.

Then, referring to FIG. 4C, an etching process is carried out to remove the exposed dielectric layer 204 and even remove a part of the semiconductor substrate 200 under the exposed dielectric layer 204 with the patterned photoresist layer 206 as a mask, so as to form the opening 208 in the semiconductor substrate 200. The bottom surface of the opening 208 is, for example, higher than the bottom surface of the conductive layer 202. In one embodiment, the bottom surface of the opening 208 is also, for example, lower than the bottom surface (not shown) of the conductive layer 202.

Then, referring to FIG. 4D, the patterned photoresist layer 206 is removed. After that, a pad 210 is formed above the semiconductor substrate 200, so as to electrically connect the conductive layer 202. The pad 210 covers the surface of the conductive layer 202 and a part of the dielectric layer 204, and fills up the opening 208. The pad 210 is, for example, a metal layer made of, for example, aluminum metal.

Then, referring to FIG. 4E, a protective layer 212 is formed to cover the surface of the dielectric layer 204 and the edge of the pad 210. The material of the protective layer 212 is, for example, an insulating material, and the forming method thereof is, for example, first forming an insulating material layer (not shown) on the dielectric layer 204 and the pad 210. Then, a part of the insulating material layer is removed, and a part of the surface of the pad 210 is exposed, thus completing the formation.

Then, the wire bonding process can be carried out subsequently, so as to electrically connect the external circuit and the pad 210 by forming the welding wire (not shown). Then, the molding step is carried out, and thus the whole semiconductor device packaging process is completed. The subsequent wire bonding and molding steps are known to the technicians in the art, and the details will not be described herein again.

It is known from the above that according to the method of the present invention, the contact area of the pad and the conductive layer under the pad is increased, and the clamping force of the pad is used to resist the upward tension in the wire bonding process, thus preventing the pad, especially the corner of the pad, from bearing the extremely high stress. The extremely high stress causes the peeling of the pad, and further damages the active circuit structure under the pad.

Similarly, compared with the method of the conventional art, the process of the present invention is not complicated, and an additional mask is not required to achieve the objective of preventing the pad from peeling, thus saving the cost of the additional mask.

The structure for preventing the pad from peeling of another embodiment of the present invention is illustrated as follows.

Referring to FIG. 4E, the structure for preventing the pad peeling of the present embodiment comprises a semiconductor substrate 200, a dielectric layer 204, a pad 210, and a protective layer 212. The semiconductor substrate 200 has an active circuit structure (not shown). In the present embodiment, only the conductive layer 202 as shown in the figure represents the active circuit structure of the semiconductor substrate 200. The semiconductor substrate 200 of the side edge of the conductive layer 202 has an opening 208. The dielectric layer 204 is disposed above the semiconductor substrate 200, and the dielectric layer 204 exposes the surface of the conductive layer 202 and the surface of a part of the semiconductor substrate 200 of the side edge of the conductive layer 202. In an embodiment, the dielectric layer 204 can further include the surface disposed on a part of the edge of the conductive layer 202 and/or the corner of the conductive layer 202. Moreover, the pad 210 is disposed above the semiconductor substrate 200 and covers the dielectric layer 202 and a part of the dielectric layer 204, and fills up the opening 208. The pad 210 is, for example, a metal layer made of, for example, aluminum metal. The protective layer 212 is disposed on the dielectric layer 204, and covers the edge of the pad 210. The material of the protective layer 212 is, for example, an insulating material.

It is known from the above that the structure of the present invention can increase the contact area of the pad and the conductive layer under the pad, and the clamping force of the pad is used to resist the upward tension in the wire bonding process, thus preventing the pad, especially the corner of the pad, from bearing the extremely high stress. The extremely high stress causes the peeling of the pad, and further damages the active circuit structure under the pad.

To sum up, the method and the structure of the present invention has at least the following advantages.

1. The method and the structure of the present invention can enhance the bonding level of the edge of the pad, especially the bonding level of the corner of the pad. Therefore, the peeling of pad which further damages the active circuit structure under the pad can be prevented.

2. The method and the structure of the present invention can increase the contact area of the pad and the conductive layer under the pad, and the clamping force of the pad is used to resist the upward tension in the wire bonding process, such that the peeling of pad which further damages the active circuit structure under the pad can be prevented.

3. Compared with the convention art, the method of the present invention is not complicated, and the cost of the additional mask can be saved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating the structure for preventing the pad peeling, comprising:
providing a semiconductor substrate in which an active circuit structure has been formed;
forming a dielectric layer with an opening on the semiconductor substrate, wherein the opening is formed in the dielectric layer above the edge position of the corresponding active circuit structure, and exposes a part of the surface of the active circuit structure;
forming a pad above the semiconductor substrate to electrically connect the active circuit structure, wherein the pad covers the dielectric layer above the position of the corresponding active circuit structure and fills up the opening; and
forming a protective layer to cover the surface of the dielectric layer and the edge of the pad.

2. The method of fabricating the structure for preventing the pad peeling as claimed in claim 1, wherein the pad comprises a metal layer.

3. The method of fabricating the structure for preventing the pad peeling as claimed in claim 2, wherein the material of the metal layer comprises aluminum.

4. The method of fabricating the structure for preventing the pad peeling as claimed in claim 1, wherein the opening comprises a trench or a hole.

5. The method of fabricating the structure for preventing the pad peeling as claimed in claim 1, wherein the material of the protective layer comprises an insulating material.

6. A structure for preventing the pad peeling, comprising:
a semiconductor substrate having an active circuit structure;
a dielectric layer disposed on the semiconductor substrate and having an opening therein, wherein the opening is located in the dielectric layer above the edge position of the corresponding active circuit structure, and exposes a part of the surface of the active circuit structure;
a pad disposed above the semiconductor substrate and covering the dielectric layer above the position of the corresponding active circuit structure and filling the opening; and
a protective layer disposed on the dielectric layer and covered the edge of the pad.

7. The structure for preventing the pad peeling as claimed in claim 6, wherein the pad comprises a metal layer.

8. The structure for preventing the pad peeling as claimed in claim 7, wherein the material of the metal layer comprises aluminum.

9. The structure for preventing the pad peeling as claimed in claim 6, wherein the opening comprises a trench or a hole.

10. The structure for preventing the pad peeling as claimed in claim 6, wherein the material of the protective layer comprises an insulating material.

11. A method of fabricating the structure for preventing the pad peeling, comprising:
providing a semiconductor substrate in which an active circuit structure has been formed;
forming a dielectric layer and a patterned photoresist layer sequentially on the semiconductor substrate, wherein the patterned photoresist layer exposes the dielectric layer surface above a part of the semiconductor substrate of the corresponding active circuit structure and the side edge thereof;
performing an etching process to remove the exposed dielectric layer and a part of the semiconductor substrate under the dielectric layer with the patterned photoresist layer as a mask, so as to form an opening in the semiconductor substrate;
removing the patterned photoresist layer;
forming a pad to electrically connect the active circuit structure, wherein the pad covers the surface of the active circuit structure and a part of the dielectric layer, and fills up the opening; and
forming a protective layer to cover the surface of the dielectric layer and the edge of the pad.

12. The method of fabricating the structure for preventing the pad peeling as claimed in claim 11, wherein the patterned photoresist layer further comprises the surface covering a part of the edge and/or corner of the active circuit structure.

13. The method of fabricating the structure for preventing the pad from peeling as claimed in claim 11, wherein the pad comprises a metal layer.

14. The method of fabricating the structure for preventing the pad from peeling as claimed in claim 13, wherein the material of the metal layer comprises aluminum.

15. The method of fabricating the structure for preventing the pad from peeling as claimed in claim 11, wherein the material of the protective layer comprises an insulating material.

16. A structure for preventing the pad peeling, comprising:
a semiconductor substrate having an active circuit structure, wherein the semiconductor substrate of the side edge of the active circuit structure has an opening;
a dielectric layer disposed on the semiconductor substrate and exposing the surface of the active circuit structure and a part of the surface of the semiconductor substrate of the side edge of the active circuit structure;
a pad disposed above the semiconductor substrate and covering the active circuit structure and a part of the dielectric layer and filling up the opening; and
a protective layer disposed on the dielectric layer and covered the edge of the pad.

17. The structure for preventing the pad peeling as claimed in claim 16, wherein the dielectric layer further comprises the surface disposed on a part of the edge and/or corner of the active circuit structure.

18. The structure for preventing the pad peeling as claimed in claim 16, wherein the pad comprises a metal layer.

19. The structure for preventing the pad peeling as claimed in claim 18, wherein the material of the metal layer comprises aluminum.

20. The structure for preventing the pad peeling as claimed in claim 16, wherein the material of the protective layer comprises an insulating material.
